(19) United States
(12) Patent Application Publication
(10) Pub. No.: US 2026/0271251 A1
(43) Pub. Date: Sep. 10, 2026

(54) MODULE AND ELECTRONIC COMPONENT

(71) Applicant: Murata Manufacturing Co., Ltd., Kyoto (JP)

(72) Inventors: Junichi SAITO, Nagaokakyo-shi (JP); Masaaki MIZUSHIRO, Nagaokakyo-shi (JP)

(21) Appl. No.: 19/659,117

(22) Filed: Apr. 27, 2026

Related U.S. Application Data
(62) Division of application No. 18/178,588, filed on Mar. 6, 2023.
Application No. 18/178,588 is a continuation of application No. PCT/JP2021/032092, filed on Sep. 1, 2021.

(30) Foreign Application Priority Data
Sep. 8, 2020 (JP) 2020-150471

(51) Int. Cl. H05K 9/00; H05K 1/181; H05K 3/28

(52) U.S. Cl. CPC H05K 9/0022; H05K 1/181; H05K 3/284; H05K 2201/10015; H05K 2201/1003

(57) ABSTRACT

A module includes a substrate having main surfaces; components mounted on at least one main surface of the substrate; a sealing resin on a surface of the substrate to embed the components; and a shielding film containing Cu as a main component and covering a top surface and at least one side surface of the sealing resin, wherein a surface of the shielding film is directly covered by a first Co layer containing Co—B or Co—N as a main component, and a surface of the first Co layer is covered by a second Co layer containing Co—P as a main component.

### CROSS REFERENCE TO RELATED APPLICATION

This is a division of U.S. patent application Ser. No. 18/178,588 filed on Mar. 6, 2023, which is a continuation of International Application No. PCT/JP2021/032092 filed on Sep. 1, 2021 which claims priority from Japanese Patent Application No. 2020-150471 filed on Sep. 8, 2020. The contents of these applications are incorporated herein by reference in their entireties.

### BACKGROUND OF THE DISCLOSURE

### Field of the Disclosure

The present disclosure relates to a module and an electronic component.

### Description of the Related Art

In various high-frequency devices, electromagnetic wave noise generated by a high-frequency current may cause electronic equipment malfunction or the like. A high-frequency electronic component may be subjected to electromagnetic wave shield plating for blocking electromagnetic waves in order to reduce the electromagnetic wave noise.

For electromagnetic wave shield plating, for example, a conductive underlayer is formed on a resin package or resin housing and then a Cu shielding film having a thickness of several tens of micrometers is formed by electroless or electrolytic plating. An electroless Ni plating film or an electroless Co plating film is formed on a surface of the Cu shielding film for anti-corrosion purpose.

For example, Patent Literature 1 discloses forming a first metal layer as a shielding film by electroless Cu plating and then forming a second metal layer on a surface of the first metal layer by electroless Ni plating.

### Patent Literature

Patent Literature 1: JP 2018-502453 A

### BRIEF SUMMARY OF THE DISCLOSURE

However, Patent Literature 1 requires adding a Pd catalyst for electroless Ni plating on the surface of the Cu shielding film. A reducing agent such as hypophosphorous acid commonly used for electroless Ni plating cannot reduce (precipitate) Ni on the surface of Cu. Thus, a method is employed in which Pd as a catalyst is attached to the surface of Cu to precipitate Ni on the surface of Pd. However, adding Pd as a catalyst which involves a displacement reaction between Cu and Pd may degrade shielding characteristics because the Cu shielding film is partially dissolved in the reaction and is thus reduced in thickness. Avoiding such issues requires a thick shielding film to be formed in advance, taking into account a reduction in thickness by Pd displacement reaction.

The same issues arise when a surface of a Cu shielding film is subjected to electroless Co plating.

The present disclosure was made to solve the above issues and aims to provide a module and an electronic component which do not cause degradation of shielding characteristics associated with dissolution of the Cu shielding film or require an increase in the thickness of the Cu shielding film.

In a first embodiment, a module of the present disclosure includes a substrate having main surfaces; a component mounted on at least one main surface of the substrate; a sealing resin on a surface of the substrate to embed the component; and a shielding film containing Cu as a main component and covering a top surface and at least one side surface of the sealing resin, wherein a surface of the shielding film is directly covered by a first Ni layer containing Ni—B or Ni—N as a main component, and a surface of the first Ni layer is covered by a second Ni layer containing Ni—P as a main component.

In a second embodiment, a module of the present disclosure includes a substrate having main surfaces; a component mounted on at least one main surface of the substrate; a sealing resin on a surface of the substrate to embed the component; and a shielding film containing Cu as a main component and covering a top surface and at least one side surface of the sealing resin, wherein a surface of the shielding film is directly covered by a first Co layer containing Co—B or Co—N as a main component, and a surface of the first Co layer is covered by a second Co layer containing Co—P as a main component.

In a first embodiment, an electronic component of the present disclosure includes a ceramic body; and a shielding film containing Cu as a main component and covering a top surface and at least one side surface of the ceramic body, wherein a surface of the shielding film is directly covered by a first Ni layer containing Ni—B or Ni—N as a main component, and a surface of the first Ni layer is covered by a second Ni layer containing Ni—P as a main component.

In a second embodiment, an electronic component of the present disclosure includes a ceramic body; and a shielding film containing Cu as a main component and covering a top surface and at least one side surface of the ceramic body, wherein a surface of the shielding film is directly covered by a first Co layer containing Co—B or Co—N as a main component, and a surface of the first Co layer is covered by a second Co layer containing Co—P as a main component.

The present disclosure can provide a module and an electronic component which do not cause degradation of shielding characteristics associated with dissolution of the Cu shielding film or require an increase in the thickness of the Cu shielding film.

### BRIEF DESCRIPTION OF THE SEVERAL VIEWS OF THE DRAWINGS

FIG. 1 is a schematic cross-sectional view of an example module of the present disclosure.

FIG. 2 is a schematic cross-sectional view of an example electronic component of the present disclosure.

### DETAILED DESCRIPTION OF THE DISCLOSURE

Hereinafter, the module and the electronic component of the present disclosure are described.

The present disclosure is not limited to the following preferred embodiments, and may be suitably modified without departing from the gist of the present disclosure. Combinations of two or more preferred features described in the following preferred embodiments are also within the scope of the present disclosure.

### Module According to First Embodiment

In a first embodiment, the module of the present disclosure includes a substrate having main surfaces; a component mounted on at least one main surface of the substrate; a sealing resin on a surface of the substrate to embed the component; and a shielding film containing Cu as a main component and covering a top surface and at least one side surface of the sealing resin, wherein a surface of the shielding film is directly covered by a first Ni layer containing Ni—B or Ni—N as a main component, and a surface of the first Ni layer is covered by a second Ni layer containing Ni—P as a main component.

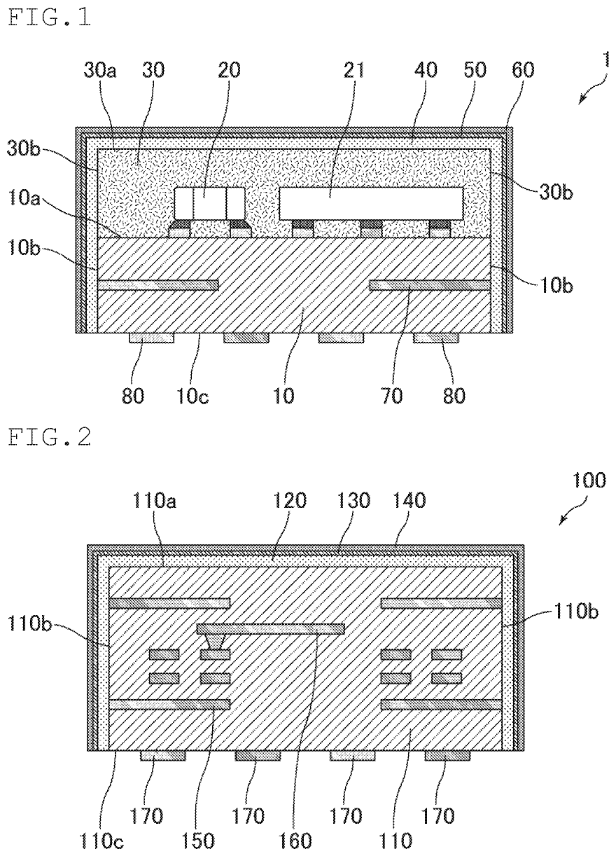

FIG. 1 is a schematic cross-sectional view of an example module of the present disclosure.

As shown in FIG. 1, a module 1 includes a substrate 10 having main surfaces, components 20 and 21 mounted on one main surface 10a of the substrate 10, a sealing resin 30 on a surface of the substrate 10 to embed the components 20 and 21, and a shielding film 40 containing Cu as a main component and covering a top surface 30a and side surfaces 30b of the sealing resin 30.

The shielding film 40 covers the top surface 30a and the side surfaces 30b of the sealing resin in a continuous manner. Thus, the shielding film 40 covers surfaces of edges where the top surface 30a and the side surfaces 30b of the sealing resin are connected to each other.

The side surfaces 30b of the sealing resin 30 are flush with respective side surfaces 10b of the substrate 10. Thus, the shielding film 40 covers the side surfaces 30b of the sealing resin 30 and the side surfaces 10b of the substrate 10 in a continuous manner.

Ground electrodes 70 are exposed on the side surfaces 10b of the substrate 10 and electrically connected to the shielding film 40. External terminals 80 for mounting the module 1 onto a mounting substrate are on a bottom surface 10c of the substrate 10.

The shielding film contains Cu as a main component.

Herein, the term “main component” refers to a component accounting for 90 wt % or more of the total.

The thickness of the shielding film is not limited and may be, for example, 0.5 μm or more and 10 μm or less.

The shielding film may be formed by any method, such as electroless plating or sputtering.

The surface of the shielding film 40 is directly covered by a first Ni layer 50.

The first Ni layer 50 contains Ni—B or Ni—N as a main component.

Ni—B is a nickel alloy containing boron (B) as an impurity.

The amount of B in Ni—B may be, for example, 0.05 wt % or more and 3 wt % or less.

Ni—N is a nickel alloy containing nitrogen (N) as an impurity.

The amount of N in Ni—N may be, for example, 0.05 wt % or more and 3 wt % or less.

Preferably, the first Ni layer 50 is made of Ni—B. Ni—B is more easily available than Ni—N.

A surface of the first Ni layer 50 is covered by a second Ni layer 60.

The second Ni layer 60 contains Ni—P as a main component.

The thickness relationship between the first Ni layer and the second Ni layer is not limited. For example, the thickness of the second Ni layer may be equal to or greater than the thickness of the first Ni layer. The amount of the first Ni layer formation per unit time is small and the stability of a plating bath of the first Ni layer is low as compared to the second Ni layer, so that the production cost of the first Ni layer tends to be high. The surface of the second Ni layer is often subjected to Au displacement plating to improve solder wettability. Thus, when there are limitations on the total thickness of the first Ni layer and the second Ni layer, the thickness of the second Ni layer is set to be equal to or greater than the thickness of the first Ni layer, whereby the stability of Au displacement plating on the surface of the second Ni layer can be increased while the production cost is reduced.

Ni—P is a nickel alloy containing phosphorus (P) as an impurity.

The amount of P in Ni—P may be, for example, 1 wt % or more and 11 wt % or less.

The compositions of the first Ni layer and the second Ni layer can be measured by inductively coupled plasma (ICP) emission spectrometry.

Whether the surface of the shielding film 40 is directly covered by the first Ni layer 50 can be determined by scanning electron microscope (SEM)-energy dispersive X-ray spectroscopy (EDX) or the like.

Specifically, for example, the module is cut to expose an interface between the shielding film 40 and the first Ni layer 50. SEM-EDX analysis of the interface can determine whether the first Ni layer 50 is directly on the surface of the shielding film 40.

For example, when the first Ni layer 50 is on the surface of the shielding film 40 via a Pd layer, SEM-EDX can identify a layer containing Pd between the shielding film 40 and the first Ni layer 50. In contrast, when the first Ni layer 50 is directly on the surface of the shielding film 40, no such layer containing Pd can be identified by SEM-EDX.

In the module according to the first embodiment of the present disclosure, the surface of the shielding film is directly covered by the first Ni layer. This prevents degradation of shielding characteristics associated with dissolution of the shielding film. In addition, since there is no need to take into account the dissolution of the shielding film, there is no need to increase the thickness of the shielding film.

The first Ni layer can be directly formed on the surface of the shielding film by a method such as electroless Ni plating using a reducing agent having a catalytic activity on Cu.

Examples of the reducing agent having a catalytic activity on Cu include dimethylamine borane, sodium boron hydride, and hydrazine.

Electroless Ni plating using the reducing agent can form a Ni layer (first Ni layer) directly on the surface of the shielding film containing Cu as a main component without involving Pd.

The substrate of the module may be a ceramic substrate or a resin substrate.

At least one ground electrode electrically connected to the shielding film is exposed on one of the side surfaces of the substrate.

The ground electrode may contain Cu or Ag as a main component.

The substrate may include a terminal (electrode) for mounting a component.

Any type of components can be used in the module of the present disclosure. For example, capacitors, thermistors, coils, resistors, diodes, switching elements, ICs, composite products thereof, and the like can be used. Two or more of these components may be disposed on the substrate.

Examples of the sealing resin include an epoxy resin, a phenolic resin, a polyimide resin, and liquid crystal polymers.

The sealing resin may contain filler such as silica particles or alumina particles.

### Module According to Second Embodiment

In a second embodiment, the module of the present disclosure includes a substrate having main surfaces; a component mounted on at least one main surface of the substrate; a sealing resin on a surface of the substrate to embed the component; and a shielding film containing Cu as a main component and covering a top surface and at least one side surface of the sealing resin, wherein a surface of the shielding film is directly covered by a first Co layer containing Co—B or Co—N as a main component, and a surface of the first Co layer is covered by a second Co layer containing Co—P as a main component.

The module according to the second embodiment of the present disclosure is obtained by changing Ni to Co in the module according to the first embodiment of the present disclosure. Thus, the module according to the second embodiment of the present disclosure is the same as the module according to the first embodiment of the present disclosure, except for the difference mentioned above.

In the module according to the second embodiment of the present disclosure, the surface of the shielding film is directly covered by the first Co layer. This prevents degradation of shielding characteristics associated with dissolution of the shielding film. In addition, since there is no need to take into account the dissolution of the shielding film, there is no need to increase the thickness of the shielding film.

### Electronic Component According to First Embodiment

In a first embodiment, the electronic component of the present disclosure includes a ceramic body; and a shielding film containing Cu as a main component and covering a top surface and at least one side surface of the ceramic body, wherein a surface of the shielding film is directly covered by a first Ni layer containing Ni—B or Ni—N as a main component, and a surface of the first Ni layer is covered by a second Ni layer containing Ni—P as a main component.

FIG. 2 is a schematic cross-sectional view of an example electronic component of the present disclosure.

As shown in FIG. 2, an electronic component 100 includes a ceramic body 110 and a shielding film 120 containing Cu as a main component and covering a top surface 110a and side surfaces 110b of the ceramic body 110.

The shielding film 120 covers the top surface 110a and the side surfaces 110b of the ceramic body 110 in a continuous manner. Thus, the shielding film 120 covers surfaces of edges where the top surface 110a and the side surfaces 110b of the ceramic body 110 are connected to each other.

The shielding film 120 contains Cu as a main component.

A surface of the shielding film 120 is directly covered by a first Ni layer 130. A surface of the first Ni layer 130 is covered by a second Ni layer 140.

Ground electrodes 150 electrically connected to the shielding film 120 are exposed on the side surfaces 110b of the ceramic body 110. The ceramic body 110 includes internal wires 160 inside thereof. External terminals 170 for mounting the electronic component 100 onto a substrate or the like are on a bottom surface 110c of the ceramic body 110.

A surface of the shielding film 120 is directly covered by the first Ni layer 130.

The first Ni layer 130 contains Ni—B or Ni—N as a main component.

Ni—B is a nickel alloy containing boron (B) as an impurity.

The amount of B in Ni—B may be, for example, 0.05 wt % or more and 3 wt % or less.

Ni—N is a nickel alloy containing nitrogen (N) as an impurity.

The amount of N in Ni—N may be, for example, 0.05 wt % or more and 3 wt % or less.

Preferably, the first Ni layer 130 is made of Ni—B. Ni—B is more easily available than Ni—N.

A surface of the first Ni layer 130 is covered by the second Ni layer 140.

The second Ni layer 140 contains Ni—P as a main component.

The thickness relationship between the first Ni layer and the second Ni layer is not limited. For example, the thickness of the second Ni layer may be equal to or greater than the thickness of the first Ni layer. The amount of the first Ni layer formation per unit time is small and the stability of a plating bath of the first Ni layer is low as compared to the second Ni layer, so that the production cost of the first Ni layer tends to be high. The surface of the second Ni layer is often subjected to Au displacement plating to improve solder wettability. Thus, when there are limitations on the total thickness of the first Ni layer and the second Ni layer, the thickness of the second Ni layer is set to be equal to or greater than the thickness of the first Ni layer, whereby the stability of Au displacement plating on the surface of the second Ni layer can be increased while the production cost is reduced.

Ni—P is a nickel alloy containing phosphorus (P) as an impurity.

The amount of P in Ni—P may be, for example, 1 wt % or more and 11 wt % or less.

The compositions of the first Ni layer and the second Ni layer can be measured by inductively coupled plasma (ICP) emission spectrometry.

Whether the surface of the shielding film 120 is directly covered by the first Ni layer 130 can be determined by scanning electron microscope (SEM)-energy dispersive X-ray spectroscopy (EDX) or the like.

Specifically, for example, the electronic component is cut to expose an interface between the shielding film 120 and the first Ni layer 130. SEM-EDX analysis of the interface can determine whether the first Ni layer 130 is directly on the surface of the shielding film 120.

For example, when the first Ni layer 130 is on the surface of the shielding film 120 via a Pd layer, SEM-EDX can identify a layer containing Pd between the shielding film 120 and the first Ni layer 130. In contrast, when the first Ni layer 130 is directly on the surface of the shielding film 120, no such layer containing Pd can be identified by SEM-EDX.

Examples of the ceramic body include capacitors, thermistors, coils, resistors, diodes, switching elements, ICs, and composite products thereof. The ceramic body may be one installed with two or more of these functions.

### Electronic Component According to Second Embodiment

In a second embodiment, the electronic component of the present disclosure includes a ceramic body; and a shielding film containing Cu as a main component and covering a top surface and at least one side surface of the ceramic body, wherein a surface of the shielding film is directly covered by a first Co layer containing Co—B or Co—N as a main component, and a surface of the first Co layer is covered by a second Co layer containing Co—P as a main component.

The electronic component according to the second embodiment of the present disclosure is obtained by changing Ni to Co in the electronic component according to the first embodiment of the present disclosure. Thus, the electronic component according to the second embodiment of the present disclosure is the same as the electronic component according to the first embodiment of the present disclosure, except for the difference mentioned above.

In the electronic component according to the second embodiment of the present disclosure, the first Co layer containing Co—B or Co—N as a main component is directly on the surface of the shielding film. This prevents degradation of shielding characteristics associated with dissolution of the shielding film. In addition, since there is no need to take into account the dissolution of the shielding film, there is no need to increase the thickness of the shielding film.

The electronic component of the present disclosure is applicable, for example, to LC filters and the like.

### EXAMPLES

Examples that more specifically disclose the substrate of the present disclosure are described below. The present disclosure is not limited to these examples.

### Example 1

Mounting of Component onto Substrate and Sealing by Sealing Resin

After mounting components onto one of main surfaces of an alumina substrate, the alumina substrate was sealed by a sealing resin such that the components were embedded. The top view dimensions of the sealing resin match the top view dimensions of the substrate, and side surfaces of the sealing resin were flush with respective side surfaces of the substrate. One or more ground electrodes were exposed on the side surfaces of the substrate.

### Formation of Shielding Film

A 1 μm-thick shielding film containing Cu as a main component was formed by sputtering on a top surface and side surfaces of the sealing resin as well as side surfaces of the substrate.

### Formation of First Ni Layer

Subsequently, the workpiece was immersed in a plating bath having a composition shown below for 10 minutes to form a first Ni layer by electroless nickel plating directly on a surface of the shielding film. The thickness of the first Ni layer formed was 1 μm as measured by a fluorescent X-ray film thickness meter.

### Composition of Plating Bath

0.02 M nickel sulfate
0.02 M dimethylamine borane
0.1 M glycine
Temperature: 50° C.
pH: 6.5

### Formation of Second Ni Layer

Subsequently, the workpiece was immersed in a plating bath having a composition shown below for 10 minutes to form a second Ni layer by electroless nickel plating on surfaces (a top surface and side surfaces) of the first Ni layer. The thickness of the second Ni layer formed was 1 μm as measured by a fluorescent X-ray film thickness meter.

### Composition of Plating Bath

0.1 M nickel sulfate
0.25 M sodium hypophosphite
0.3 M glycine
Temperature: 80° C.
pH: 4.5

A module according to Example 1 was obtained by the above procedure.

Measurement of Compositions of First Ni Layer and Second Ni Layer

The second Ni layer was dissolved in aqua regia to obtain a sample. The sample was analyzed by ICP emission spectrometry, whereby the composition of the second Ni layer was measured. The second Ni layer was a Ni—P layer containing 8 wt % phosphorus (P) and 92 wt % nickel (Ni).

The second Ni layer was removed by polishing to expose the first Ni layer. By the same procedure used for the second Ni layer, the first Ni layer was dissolved in aqua regia to obtain a sample, and the sample was analyzed by ICP emission spectrometry, whereby the composition of the first Ni layer was measured. The first Ni layer was a Ni—B layer containing 1 wt % boron (B) and 99 wt % nickel (Ni).

### Example 2

A module according to Example 2 was produced by the same procedure as in Example 1, except that the composition of the plating bath for forming the first Ni layer was changed as described below, and the immersion time was changed to 20 minutes.

### Composition of Plating Bath

0.05 M nickel sulfate
0.4 M hydrazine
0.3 M glycine
0.5 M boric acid
Temperature: 85° C.
pH: 12

The compositions of the second Ni layer and the first Ni layer were measured by ICP emission spectrometry. The second Ni layer was a Ni—P layer containing 8 wt % phosphorus (P) and 92 wt % nickel (Ni) as in Example 1. In contrast, the first Ni layer was a Ni—N layer containing 0.5 wt % nitrogen (N) and 99.5 wt % nickel (Ni).

### Comparative Example 1

A module according to Comparative Example 1 was produced by the same procedure as in Example 1, except that Pd displacement was performed on the surface of the shielding film instead of forming the first Ni layer thereon.

### Observation of Interface Between Shielding Film and First Ni Layer

The modules according to Examples 1 and 2 and Comparative Example 1 were each cut to expose an interface between the shielding film and the Ni layer. The interface was observed by SEM-EDX to check for another layer between the shielding film and the Ni layer. Table 1 shows the results.

### Measurement of Shielding Characteristics

The shielding characteristics of the modules according to Examples 1 and 2 and Comparative Example 1 were measured by the following method. Table 1 shows the results.

Using a shield box or shield room, the behavior of each of the modules according to Examples 1 and 2 and Comparative Example 1 upon emission of electromagnetic interference waves was measured by a high-frequency device measurement instrument. Specifically, electromagnetic interference waves were emitted while operating the module, and the signal level emitted by the module was measured. Entrance of electromagnetic interference waves into the module in operation causes an increase in the signal level emitted by the module, but the module shielding effect controls the signal level not to exceed a predetermined level. The signal loss was measured by measuring the level of signals from a specific portion to an input side A and the level of signals from the specific portion to an output side B as signals ranging from 0.96 to 1.16 GHZ emitted from the module upon emission of electromagnetic interference waves having a frequency of 1 GHZ. A signal analyzer or a network analyzer (Keysight Technologies) was used as the measurement instrument. The difference between the signal level at the input side A and the signal level at the output side B was determined to measure the signal loss L. The shielding characteristics were determined as not being degraded when the signal loss L was 50 dB or less.

TABLE 1

| | Shielding film | | Layer between | First Ni layer | | Second Ni layer | | |
|---|---|---|---|---|---|---|---|---|
| | Main | Thickness | shielding film | Main | Thickness | Main | Thickness | Shielding |
| | component | [μm] | and first Ni layer | component | [μm] | component | [μm] | characteristics |
| Example 1 | Cu | 1 | — | Ni-B | 1 | Ni-P | 1 | Not degraded |
| Example 2 | Cu | 1 | — | Ni-N | 1 | Ni-P | 1 | Not degraded |
| Comparative | Cu | 1 | Pd layer | — | — | Ni-P | 1 | Degraded |
| Example 1 | | | | | | | | |

The results in Table 1 show that the module of the present disclosure prevents degradation of shielding characteristics.
1 module
10 substrate
10a one main surface of substrate
10b side surface of substrate
10c bottom surface of substrate
20, 21 component
30 sealing resin
30a top surface of sealing resin
30b side surface of sealing resin
40 shielding film
50 first Ni layer
60 second Ni layer
70 ground electrode
80 external terminal
100 electronic component
110 ceramic body
110a top surface of ceramic body
110b side surface of ceramic body
110c bottom surface of ceramic body
120 shielding film
130 first Ni layer
140 second Ni layer
150 ground electrode
160 internal wire
170 external terminal

1. A module comprising:
a substrate having main surfaces;
a component mounted on at least one of the main surfaces of the substrate;
a sealing resin on a surface of the substrate to embed the component; and
a shielding film containing Cu as a main component and covering a top surface and at least one side surface of the sealing resin,
wherein a surface of the shielding film is directly covered by a first Co layer containing Co—B or Co—N as a main component, and
a surface of the first Co layer is covered by a second Co layer containing Co—P as a main component.

2. The module according to claim 1,
wherein a surface of an edge where the top surface and the side surface of the sealing resin are connected to each other is covered by the shielding film, and
a surface of the shielding film covering the surface of the edge is directly covered by the first Co layer.

3. The module according to claim 1,
wherein a thickness of the second Co layer is equal to or greater than a thickness of the first Co layer.

4. An electronic component comprising:
a ceramic body; and
a shielding film containing Cu as a main component and covering a top surface and at least one side surface of the ceramic body,
wherein a surface of the shielding film is directly covered by a first Co layer containing Co—B or Co—N as a main component, and
a surface of the first Co layer is covered by a second Co layer containing Co—P as a main component.

5. The electronic component according to claim 4,
wherein a surface of an edge where a top surface and to a side surface of the ceramic body are connected to each other is covered by the shielding film, and
a surface of the shielding film covering the surface of the edge is directly covered by the first Co layer.

6. The electronic component according to claim 4,
wherein a thickness of the second Co layer is equal to or greater than a thickness of the first Co layer.

7. The module according to claim 2,
wherein a thickness of the second Co layer is equal to or greater than a thickness of the first Co layer.

8. The electronic component according to claim 5,
wherein a thickness of the second Co layer is equal to or greater than a thickness of the first Co layer.

9. The electronic component according to claim 4,
wherein the electronic component is used as an LC filter.
